(19) United States
(12) Patent Application Publication
(10) Pub. No.: US 2013/0026477 A1
(43) Pub. Date: Jan. 31, 2013

(54) FLAT PANEL DISPLAY DEVICE AND METHOD OF MANUFACTURING THE SAME

(71) Applicant: Hyun-Been HWANG, Yongin-City (KR)

(72) Inventor: Hyun-Been HWANG, Yongin-City (KR)

(21) Appl. No.: 13/472,766

(22) Filed: May 16, 2012

(30) Foreign Application Priority Data
Jul. 29, 2011 (KR) 10-2011-0076142

(51) Int. Cl. H01L 27/15; H01L 33/08

(52) U.S. Cl. 257/59; 438/34; 257/E33.004; 257/E27.121

(57) ABSTRACT

A flat panel display device includes a substrate having an emission area in which an image is displayed and a pad area that is outside of the emission area, a semiconductor layer on the substrate, and the semiconductor layer has crystallization areas and amorphous areas. An electrostatic protecting circuit is on a portion of at least one of the amorphous areas corresponding to the pad area, and a panel circuit unit is on a portion of at least one of the crystallization areas corresponding to the pad area.

### CROSS-REFERENCE TO RELATED PATENT APPLICATION

This application claims the benefit of Korean Patent Application No. 10-2011-0076142, filed on Jul. 29, 2011, in the Korean Intellectual Property Office, the disclosure of which is incorporated herein in its entirety by reference.

### BACKGROUND

A flat panel display device, e.g., an organic light-emitting display device and a liquid crystal display device, may be fabricated on a substrate. The substrate may include a pattern having at least a thin film transistor (TFT), a capacitor, and a wire connecting the TFT and the capacitor is formed.

### SUMMARY

Embodiments may be realized by providing a flat panel display device including a substrate having an emission area in which an image is displayed and a pad area that is outside of the emission area, a semiconductor layer formed on the substrate and having crystallization areas and amorphous areas, an electrostatic protecting circuit formed on the amorphous areas corresponding to the pad area, and a panel circuit unit formed on the crystallization areas corresponding to the pad area.

The crystallization areas each may have polycrystalline silicon, and the amorphous area may each include amorphous silicon. The crystallization areas and the amorphous areas may be formed in a first direction of the substrate. The crystallization areas and the amorphous areas may be alternately formed in a second direction crossing the first direction of the substrate. The first direction and the second direction may be perpendicular to each other.

The panel circuit unit may include a scan driver or a data driver. The emission area may be in a central portion of the substrate, and the pad area may be adjacent to at least one side of the emission area. A pixel circuit unit may be formed on the crystallization area corresponding to the emission area. The pixel circuit unit may have a thin film transistor (TFT) or a capacitor. An active layer of the TFT may be formed of the crystallization area.

Embodiments may also be realized by providing a method of manufacturing a flat panel display device, the method including preparing a substrate having an emission area in which an image is displayed and a pad area that is outside of the emission area, forming a semiconductor layer on the substrate, forming crystallization areas and amorphous areas by selectively crystallizing the semiconductor layer, forming a panel circuit unit on the crystallization areas corresponding to the pad area, and forming an electrostatic protecting circuit the amorphous areas corresponding to the pad area.

The crystallization areas may be formed of polycrystalline silicon, and the amorphous areas may each include amorphous silicon. The crystallization areas and the amorphous areas may be formed in a first direction of the substrate. The crystallization areas and the amorphous areas may be alternately formed in a second direction crossing the first direction of the substrate.

The panel circuit unit may have a scan driver or a data driver. The emission area may be in a central portion of the substrate, and the pad area may be adjacent at least one side of the emission area. A pixel circuit unit may be formed on the crystallization areas corresponding to the emission area. The pixel circuit unit may have a thin film transistor (TFT) or a capacitor.

### BRIEF DESCRIPTION OF THE DRAWINGS

Features will become apparent to those of ordinary skill in the art by describing in detail exemplary embodiments with reference to the attached drawings in which:

FIG. 1 illustrates a cross-sectional view of a thin film transistor (TFT) that is a pixel circuit unit, according to an exemplary embodiment;

FIG. 2 illustrates a plan view of a substrate, according to an exemplary embodiment;

FIG. 3 illustrates a perspective view of a semiconductor layer and a substrate, according to an exemplary embodiment; and

FIG. 4 illustrates a schematic plan view of a portion of a flat panel display device, according to an exemplary embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will also be understood that when a layer is referred to as being “between” two layers, it can be the only layer between the two layers, or one or more intervening layers may also be present. Like reference numerals refer to like elements throughout.

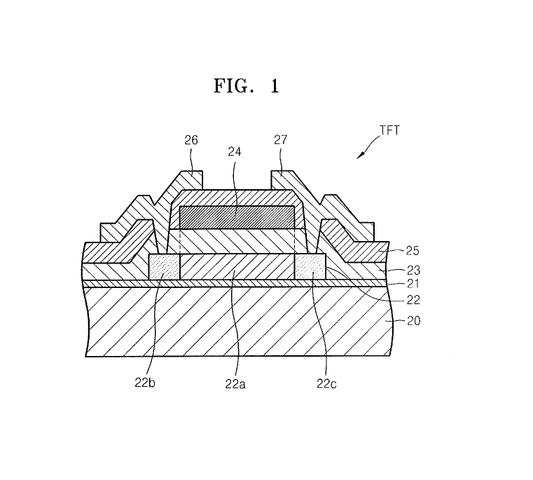

FIG. 1 illustrates a cross-sectional view of a thin film transistor (TFT) that is a pixel circuit unit, according to an exemplary embodiment.

Referring to FIG. 1, the TFT may be formed on a substrate 20. The substrate 20 may be, e.g., a glass substrate or a plastic substrate.

A buffer layer 21 may be formed on the substrate 20 and an active layer 22 may be formed on the buffer layer 21. A gate insulating layer 23 may be formed on the buffer layer 21 to cover the active layer 22. A gate electrode 24 may be formed on the gate insulating layer 23. An insulating interlayer 25 may be formed on the gate insulating layer 23 to cover the gate electrode 24. Source and drain electrodes 26 and 27 may be formed on the insulating interlayer 25. The source and drain electrodes 26 and 27 may respectively contact source and drain regions 22b and 22c of the active layer 22 via, e.g., contact holes extending through the gate insulating layer 23 and the insulating interlayer 25.

The active layer 22 foamed on the substrate 20 may be formed of, e.g., an inorganic semiconductor or an organic semiconductor. The active layer 22 may include the source and drain regions 22b and 22c, e.g., disposed on opposing ends thereof. The source and drain regions 22b and 22c may be doped with one of n-type or p-type impurities. The active layer 22 may include a channel region 22a connecting the source and drain regions 22b and 22c.

The inorganic semiconductor for forming the active layer 22 may include at least one of, e.g., cadmium sulfide (CdS), gallium sulfide (GaS), zinc sulfide (ZnS), cadmium selenide (CdSe), calcium selenide (CaSe), zinc selenide (ZnSe), cadmium telluride (CdTe), silicon carbide (SiC), and silicon (Si).

The organic semiconductor for forming the active layer 22 may include at least one of, e.g., polythiophene or a derivative thereof, poly(paraphenylene vinylene) or a derivative thereof, polyparaphenylene or a derivative thereof, polyfluorene or a derivative thereof, polythiophene vinylene or a derivative thereof, and polythiophene-heterocyclic aromatic copolymer or a derivative thereof, as a high molecular material. The organic semiconductor may include one at least one of, e.g., pentacene, tetracene, oligoacene of naphthalene or a derivative thereof, alpha-6-thiophene, oligothiophene of alpha-5-thiophene or a derivative thereof, phtalocyanine with or without metal or a derivative thereof, pyromellitic dianhydride or a derivative thereof, pyromellitic diimide or a derivative thereof, perylenetetracarboxylic acid dianhydride or perylene carboxylic diimide or a derivative thereof as a low molecular material. According to an exemplary embodiment, the organic semiconductor may include only the high molecular material or the low molecular material, e.g., only one of the high molecular material or one of the low molecular material.

The active layer 22 may be covered by the gate insulating layer 23. The gate electrode 24 may be formed on the gate insulating layer 23. The gate electrode 24 may be formed of a conductive metal layer including, e.g., at least one of molybdenum-tungsten (MoW), aluminum (Al), chromium (Cr), or aluminum/copper (Al/Cu). However, embodiments are not limited thereto, e.g., any of various conductive materials may be used. For example, a conductive polymer may be used as the gate electrode 24. The gate electrode 24 may be formed to cover an area corresponding to the channel region 22a of the active layer 22.

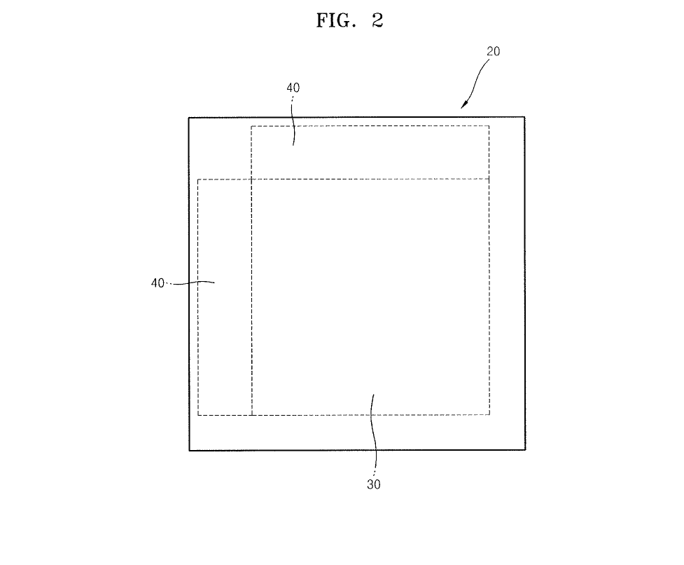

FIG. 2 illustrates a plan view of a substrate, according to an exemplary embodiment.

Referring to FIG. 2, the substrate 20 may be divided into an emission area 30 and at least one pad area 40. The emission area 30 may be a central portion of the substrate 20. The pad area 40 may be at an edge portion of the emission area 30, e.g., between the edge portion of the emission area 30 and an edge portion of the substrate 20. The pad area 40 may be adjacent to, e.g., may abut, at least one side of the emission area 30. According to an exemplary embodiment, the substrate 20 may include two pad areas 40 that may be at left and upper portions, respectively, of the emission area 30, e.g., as illustrated in FIG. 2.

A plurality of pixels may be formed on the emission area 30. For example, each pixel may include an emission portion where light is emitted to display a predetermined image.

According to an exemplary embodiment, the emission portion may include a plurality of sub-pixels that each includes an organic electro-luminescence device. In a full-color organic electro-luminescence device, red (R), green (G), and blue (B) sub-pixels may be arranged with any of various patterns, e.g., a line shape, a mosaic shape, or a lattice shape to form a pixel. A mono-color flat panel display device may be used instead of a full-color flat panel display device.

Devices capable of, e.g., controlling an image signal that is input to the pixels formed on the emission area 30, may be formed on the pad area 40. In such an organic light-emitting display device, at least one TFT may be formed on the emission area 30 and the pad area 40.

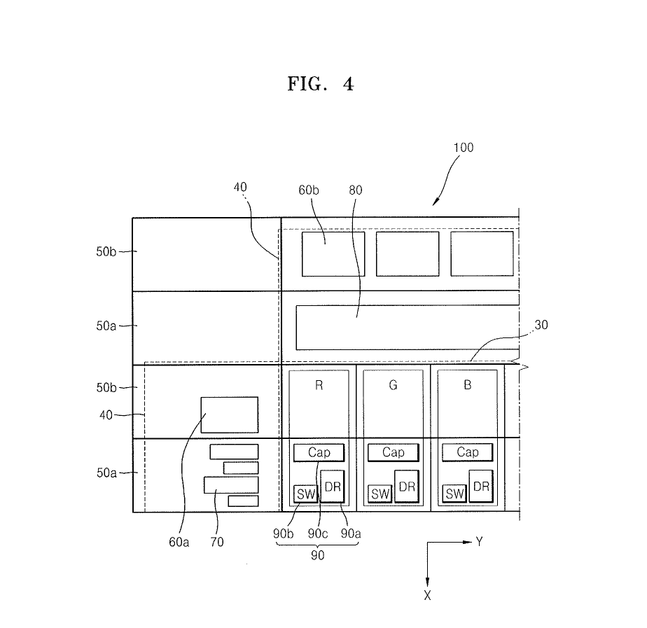

The TFT formed on the emission area 30 may be, e.g., a pixel unit TFT including a switching TFT 90b and a driving TFT 90a (see FIG. 4). The switching TFT 90b may be for sending a data signal to the organic electro-luminescence device according to a signal of a gate line to, e.g., control an operation of the organic electro-luminescence device. The driving TFT 90a may be for driving, e.g., to apply a predetermined current to the organic electro-luminescence device according to the data signal. The devices formed on the pad area 40 may be, e.g., a scan driver 70 (see FIG. 4) and/or a data driver 80 (see FIG. 4), formed to configure a predetermined circuit.

The number and arrangement of the TFTs may vary according to a characteristic of a display device or a method of driving the display device. A method of arranging the TFTs may vary.

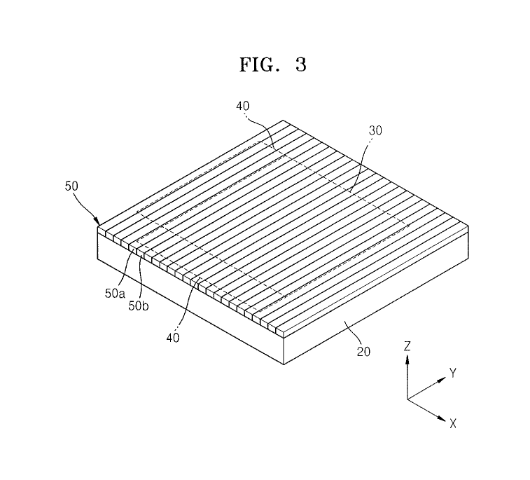

FIG. 3 illustrates a perspective view of the substrate 20 on which a semiconductor layer 50 may be formed, according to an exemplary embodiment.

Referring to FIG. 3, according to an exemplary embodiment, the semiconductor layer 50 may be formed on the substrate 20. The semiconductor layer 50 may include, e.g., crystallization areas 50a and amorphous areas 50b. The crystallization area 50a may be formed of polycrystalline silicon, and the amorphous area 50b may be formed of amorphous silicon. The crystallization areas 50a and the amorphous areas 50b may be formed extending along and/or elongated in a first direction, e.g., a Y-axis direction. For example, ones of the crystallization areas 50a and the amorphous areas 50b may extend through both one pad area 40 and the emission area 30.

The crystallization areas 50a and the amorphous areas 50b may be alternately formed in a second direction, e.g., an X-axis direction, that intersects the first direction of the substrate 20. The first direction and the second direction may cross each other at right angles. The crystallization areas 50a and the amorphous areas 50b may be parallel to each other in a same plane on the substrate 20, e.g., so that at least one lateral side abuts neighboring ones of the crystallization areas 50a or the amorphous areas 50b. Each of the crystallization areas 50a and the amorphous areas 50b may extend across the entire substrate 20 in the first direction, e.g., the crystallization areas 50a and the amorphous areas 50b may have linear shapes extending across the substrate 20.

The crystallization areas 50a may be formed by selectively crystallizing an amorphous silicon layer on the substrate 20, e.g., on the entire substrate 20. For example, the semiconductor layer 50 may be crystallized in the first direction, e.g., the Y-axis direction, of the substrate 20 so as to have a predetermined width in the second direction, e.g., the X-axis direction. Then, a predetermined interval may be formed in the second direction, e.g., the X-axis direction, of the substrate 20 prior to the semiconductor layer 50 being crystallized again in the first direction of the substrate 20. Accordingly, a predetermined width of the crystallization areas 50a in the second direction may be formed. Further, the adjacent crystallization areas 50a may be spaced apart in the second direction.

Portions of the amorphous silicon layer that are not crystallized may form the amorphous areas 50b. The amorphous areas 50b may be spaced apart on the substrate 20, e.g., ones of the amorphous areas 50b may be between two neighboring crystallization areas 50a. Thus, as illustrated in FIG. 3, the crystallization areas 50a and the amorphous areas 50b may be alternately formed in the second direction, e.g., the X-axis direction, of the substrate 20. Although not shown in FIG. 3, a buffer layer may be formed between the substrate 20 and the semiconductor layer 50.

FIG. 4 illustrates a schematic plan view of a portion of a flat panel display device 100, according to an exemplary embodiment. The flat panel display device 100 illustrated in FIG. 4 may be an organic electro-luminescence display device. However, embodiments are not limited thereto, e.g., the flat panel display device 100 may be a liquid crystal display (LCD) device.

Referring to FIG. 4, the flat panel display device 100 may include the substrate 20 (see FIG. 3), the semiconductor layer 50 (see FIG. 3), sub-pixels R, G, and B, electrostatic protecting circuits 60a and 60b, and panel circuit units 70 and 80.

The substrate 20 may be, as described above, divided into the emission area 30 in which an image is displayed and the pad area 40 that is outside of the emission area 30. The sub-pixels R, G, and B may be formed on the emission area 30, and the electrostatic protecting circuits 60a and 60b and the panel circuit units 70 and 80 may be formed on the pad area 40. For example, one pad area 40 may include the electrostatic protecting circuit 60a and the panel circuit unit 70 as the scan driver 70, which may be spaced apart from each other. Another pad area 40 may include the electrostatic protecting circuit 60b and the panel circuit unit 80 as the data driver 80, which may be spaced apart from each other.

The semiconductor layer 50 may be, as described above, formed on the substrate 20 and may include the crystallization areas 50a and the amorphous areas 50b. The crystallization areas 50a may be formed by selectively crystallizing the semiconductor layer 50, and portions of the semiconductor layer 50 that is not crystallized may form the amorphous areas 50b.

A pixel circuit unit 90 may be formed on a portion of at least one of the crystallization areas 50a in the emission area 30. The panel circuit units 70 and 80 may each be formed on portions of at least one crystallization area 50a in the pad area 40. The electrostatic protecting circuits 60a and 60b may be formed on portions of at least one of the amorphous areas 50b in the pad areas 40. Sub-pixels R, G, and B connected to corresponding pixel circuit units 90 may be formed on portions of at least one the amorphous areas 50b in the emission area 30.

According to an exemplary embodiment, the electrostatic protecting circuit 60a may be formed on one of the amorphous areas 50b corresponding to one pad area 40, and the panel circuit unit 80 may be formed on an adjacent crystallization area 50a corresponding to the pad area 40. The electrostatic protecting circuit 60b may be formed on one of the amorphous areas 50b corresponding to one pad area 40, and the panel circuit unit 70 may be formed on an adjacent crystallization area 50a corresponding to the pad area 40. The pixel circuit unit 90 may be formed on the crystallization area 50a corresponding to the emission area 30, e.g., the pixel circuit unit 30 may be formed on the same crystallization area 50a including the panel circuit unit 70.

The sub-pixels R, G, and B and the pixel circuit unit 90 may be formed on the emission area 30. When the flat panel display device 100 is an organic light-emitting display device, the sub-pixels R, G, and B may be organic light-emitting devices. The organic light-emitting device may include an anode, an intermediate layer including an emission layer, and a cathode, e.g., subsequently stacked therein. The pixel circuit unit 90 may be electrically connected to the organic light-emitting device to apply current to the organic light-emitting device.

The pixel circuit unit 90 may include, e.g., the driving TFT 90a, the switch TFT 90b, and a storage capacitor 90c. The pixel circuit unit 90 may be formed on portions of a corresponding crystallization area 50a in the emission area 30. The corresponding crystallization area 50a may be formed of polysilicon, and the crystallization area 50a may be an active layer (not shown) of the driving TFT 90a or the switch TFT 90b or may be an electrode of the storage capacitor 90c. For example, TFTs and capacitors in pixel circuit units 90 may be formed of the crystallization areas 50a so that the crystallization areas 50 may form portions of the TFTs and capacitors.

The panel circuit units 70 and 80 may be formed on the crystallization area 50a corresponding to the pad area 40. The panel circuit units 70 and 80 may be the scan driver 70 and the data driver 80, respectively. The scan driver 70 may be connected to a scan line (not shown) of the sub-pixels R, G, and B, e.g., to apply a scan signal to the sub-pixels R, G, and B and to select one row of the sub-pixels R, G, and B. The data driver 80 may be connected to a data line (not shown) of the sub-pixels R, G, and B to, e.g., apply a data signal to the selected one row of the sub-pixels R, G, and B. The scan driver 70 and the data driver 80 may be formed of, e.g., TFTs. According to an exemplary embodiment, active layers of the TFTs may be formed by portions of corresponding crystallization areas 50a.

The electrostatic protecting circuits 60a and 60b may be formed on portions of corresponding amorphous area 50bs in to the pad area 40. The electrostatic protecting circuits 60a and 60b may be electrically connected to the pixel circuit unit 90 and/or the panel circuit units 70 and 80 so as to, e.g., protect the pixel circuit unit 90 and/or the panel circuit units 70 and 80 against static electricity.

For example, the static electricity may be generated during a manufacturing process of the flat panel display device. The flat panel display device may be formed of an insulating substrate such as a glass substrate. Because the insulating substrate is a nonconductor, charges that are generated momentarily may not be discharged below the insulating substrate, and thus the insulating substrate may be vulnerable to static electricity. Accordingly, an insulating layer, a transistor, and/or an organic light-emitting device formed on the insulating substrate may be damaged due to, e.g., the static electricity. For example, the static electricity may have an extremely high voltage and may have an extremely low amount of charges, and the static electricity may locally deteriorate the insulating substrate and enter through the scan line and the data line. Thereby, the active layer of the pixel circuit unit 90 and/or of the panel circuit units 70 and 80 may be deteriorated.

According to an exemplary embodiment, the electrostatic protecting circuits 60a and 60b may be used to, e.g., protect the pixel circuit unit 90 and/or the panel circuit units 70 and 80 against the static electricity. In the flat panel display device, the electrostatic protecting circuits 60a and 60b may be formed on the amorphous area 50b corresponding to the pad area 40 so as to, e.g., protect the flat panel display device against a high voltage static electricity.

For example, the amorphous area 50b on which the electrostatic protecting circuits 60a and 60b are formed may include amorphous silicon. The amorphous silicon may have a sheet resistance greater than that of polyscrystalline silicon by about 1000 times. Accordingly, as the amorphous silicon has a greater resistance, the amorphous silicon may be able to better withstand a momentary voltage change. As such, the electrostatic protecting circuits 60a and 60b may further effectively protect the flat panel display device against a high voltage static electricity than an electrostatic protecting circuit formed on polyscrystalline silicon.

The amorphous silicon may have an off current that is lower by about 1,000 times than that of polycrystalline silicon. As the off current decreases, the amorphous silicon may be able to better withstand a momentary voltage change. As such, the electrostatic protecting circuits 60a and 60b may further protect the flat panel display device against a high voltage static electricity than an electrostatic protecting circuit formed on polyscrystalline silicon.

According to an exemplary embodiment, the electrostatic protecting circuits 60a and 60b may be formed on the amorphous areas 50b having a high resistance and a low mobility, and the electrostatic protecting circuits 60a and 60b may protect the flat panel display device against static electricity that, e.g., may have a rapid voltage change. The panel circuit units 70 and 80 and the pixel circuit unit 90 may be formed on the crystallization areas 50a having a high charge mobility, and thus the flat panel display device may be driven at a high speed. Further, in the flat panel display device, the semiconductor layer 50 may be selectively crystallized only with respect to an area in which, e.g., the pixel circuit unit 90 and the panel circuit units 70 and 80 are to be formed. Accordingly, productivity may be increased on a large area substrate.

By way of summation and review, TFTs may include, e.g., amorphous silicon or polysilicon layers therein. Since polysilicon may have a higher field effect mobility than amorphous silicon, a device formed using the high field effect mobility, e.g., a TFT, may be used as a driving device. When a flat panel display device is manufactured using the polysilicon, the driving device may be formed in an array substrate, e.g., a driving circuit unit and the driving device together may be formed in a single substrate. Accordingly, the stage of separately attaching a printed circuit board (PCB) including a driving circuit to the flat panel display device may be eliminated.

During a process of manufacturing a flat panel display device, static electricity may be generated. A device such as a TFT or a capacitor may be damaged due to the static electricity. Thus, to protect the device from the static electricity, embodiments, e.g., the exemplary embodiments, relate to a flat panel display device that includes an electrostatic protecting circuit. Further, the flat panel display device, according to exemplary embodiments, may be protected from being damaged by static electricity and may have an enhanced productivity.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A flat panel display device, comprising:
a substrate having an emission area in which an image is displayed and a pad area that is outside of the emission area;
a semiconductor layer on the substrate, the semiconductor layer having crystallization areas and amorphous areas;
an electrostatic protecting circuit on a portion of at least one of the amorphous areas corresponding to the pad area; and
a panel circuit unit on a portion of at least one of the crystallization areas corresponding to the pad area.

2. The flat panel display device of claim 1, wherein the crystallization areas each include polycrystalline silicon and the amorphous area each include amorphous silicon.

3. The flat panel display device of claim 1, wherein the crystallization areas and the amorphous areas are elongated a first direction of the substrate.

4. The flat panel display device of claim 3, wherein the crystallization areas and the amorphous areas are alternately arranged in a second direction, the second direction crossing the first direction of the substrate.

5. The flat panel display device of claim 4, wherein the first direction and the second direction are perpendicular to each other.

6. The flat panel display device of claim 1, wherein the panel circuit unit includes a scan driver or a data driver.

7. The flat panel display device of claim 1, wherein the emission area is in a central portion of the substrate, and the pad area is adjacent to at least one side of the emission area.

8. The flat panel display device of claim 1, further comprising a pixel circuit unit on a portion of at least one of the crystallization areas corresponding to the emission area.

9. The flat panel display device of claim 8, wherein the pixel circuit unit has at least one of a thin film transistor (TFT) and a capacitor.

10. The flat panel display device of claim 9, wherein the pixel circuit unit includes the TFT, and an active layer of the TFT includes the portion of the at least one of the crystallization areas corresponding to the emission area.

11. A method of manufacturing a flat panel display device, the method comprising:
preparing a substrate having an emission area in which an image is displayed and a pad area that is outside of the emission area;
forming a semiconductor layer on the substrate;
forming crystallization areas and amorphous areas by selectively crystallizing the semiconductor layer;
forming an electrostatic protecting circuit on a portion of at least one of the amorphous areas corresponding to the pad area; and
forming a panel circuit unit on a portion of at least one of the crystallization areas corresponding to the pad area.

12. The method of claim 11, wherein the crystallization areas are formed of polycrystalline silicon, and the amorphous areas each include amorphous silicon.

13. The method of claim 11, wherein the crystallization areas and the amorphous areas are formed to extend in a first direction of the substrate.

14. The method of claim 13, wherein the crystallization areas and the amorphous areas are alternately formed in a second direction, the second direction crossing the first direction of the substrate.

15. The method of claim 11, wherein the panel circuit unit has a scan driver or a data driver.

16. The method of claim 11, wherein the emission area is in a central portion of the substrate, and the pad area is adjacent to at least one side of the emission area.

17. The method of claim 11, further comprising forming a pixel circuit unit on a portion of at least one of the crystallization areas corresponding to the emission area.

18. The method of claim 17, wherein the pixel circuit unit has at least one of a thin film transistor (TFT) and a capacitor.
